(19) United States
(12) Patent Application Publication
(10) Pub. No.: US 2005/0214658 A1
(43) Pub. Date: Sep. 29, 2005

(54) Method for alleviating tolerance restrictions for feature sizes during fabrication of photomasks

(76) Inventors: Henning Haffner, Pawling, NY (US); Peter Marek, Coswig-Brockwitz (DE); Bernd Hay, Dorfen (DE); Nina Doehr, Munchen (DE); Frank Katzwinkel, Dresden (DE); Carmen Jaehnert, Dresden (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/086,668

(22) Filed: Mar. 23, 2005

(30) Foreign Application Priority Data
Mar. 24, 2004 (DE) 10 2004 014 482.6

(51) Int. Cl. G03F 9/00; G03C 5/00

(52) U.S. Cl. 430/5; 430/30; 430/322

(57) ABSTRACT

Tolerances to be communicated to the manufacturer for a photomask fabrication process that are assigned as desired values of feature sizes to be realized on the photomask, are freed of restrictions by predefining, for a first feature size, a first desired value and a first tolerance assigned to the first desired value. The real discrepancy between the first feature size and the first desired value is taken into account when predefining desired values assigned to the further feature sizes to be provided on the photomask. As a result, a value which corresponds to a first approximation to the permitted feature size tolerance on the semiconductor wafer is provided for the tolerances of the desired values.

### CROSS REFERENCE TO RELATED APPLICATIONS

This application claims priority under 35 USC §119 to German Application No. DE 10 2004 014 482.6, filed on Mar. 24, 2004, and titled “Method for Extending Limitations for Feature Sizes in the Fabrication Process for Photomasks,” the entire contents of which are hereby incorporated by reference.

### FIELD OF THE INVENTION

The invention relates to a method for extending limitations for feature sizes in the fabrication process for structures on photomasks to be imaged onto a semiconductor wafer in order to reduce tolerance restrictions of other feature sizes to be provided on the photomask.

### BACKGROUND

A photomask has a transparent substrate covered with shielding patterns made of a light-absorbing material. The pattern impressed in the absorbing material of the photomask is imaged onto a semiconductor wafer for the formation of microstructures by a lithographic imaging device. Integrated semiconductor devices, such as a DRAM (Dynamic Random Access Memory) memory chip, for instance, may emerge, for example, from the microstructures.

The photomask is produced by a mask manufacturer and information about the specification of the photomask is conveyed to the mask manufacturer. Various structures that differ in dimensions, for example, length and width, may be provided on a photomask. A photomask may have a multiplicity of different structures such that one or a plurality of critical structures are defined in a representative manner and specified with regard to their dimensional accuracy for the mask fabrication process. In this case, the critical structures are assigned feature sizes characterized by measurement points. The feature size may correspond to a length to be measured or a width of a structure.

FIG. 1 illustrates a detail from a photomask 3 with a rectangular structure characterized by two feature sizes (1, 2). The first feature size 1 corresponds to the width and the second feature size 2 corresponds to the length of the white rectangle illustrated in FIG. 1. The mask manufacturer is informed of a first desired value 1a for the photomask for the first feature size 1 and a second desired value 2a for the second feature size 2. These desired values 1a, 2a may be derived directly and independently of one another from the geometrical design data, the photomask design hereinafter. In FIG. 1, the first desired value 1a and the second desired value 2a are identified by the middle arrow in the rectangles. The arrows a and b in FIG. 1 indicate the maximum permissible deviations upward and downward from the respective desired value 1a, 2a.

The maximum permissible deviations from the desired value are determined, for example, empirically by series of lithographic exposures. For this purpose, variations in the length or width of the feature size regarded as the most critical for the imaging fidelity, this generally being the smallest feature size, are exposed, with exposure parameters that are correspondingly adapted in the imaging device, to a target dimension to be achieved on the semiconductor wafer. Those deviations upward and downward beyond which the target dimension on the semiconductor wafer can no longer be achieved by an adaptation of exposure parameters specify the upper and lower tolerance limits. The upper and lower tolerance limits for the feature size are thus derived from the resulting lithography process window. The permissible tolerances for the other feature sizes can be determined from the tolerance for the critical feature size. Tolerance is to be understood in this case to mean a tolerance range, i.e., the interval between the upper and lower tolerance limits.

In a real lithography process, there is generally only one target dimension on the semiconductor wafer, to which the imaging process is set and at which the procedure is directed by adaptation of the exposure dose. In the example described in FIG. 1, the first feature size is assigned the target dimension on the semiconductor wafer since the smallest, the most critical, feature size is involved in this example. However, this procedure cannot prevent the fact that, as a result of adaptation of the exposure dose for the most critical feature size, feature size dimensions on the semiconductor wafer are to a first approximation concomitantly altered linearly for the further feature sizes. The real acceptable tolerances that are to be assigned to the further feature sizes on the mask thus correspond to a first approximation to the difference between the permitted tolerance of the first feature size and the permitted tolerance of the further feature sizes.

The described coupling of the feature sizes is illustrated once again in FIG. 2. FIG. 2 illustrates the first feature size 1 and the first desired value 1a assigned to the first feature size 1 on the photomask. The arrows a and b specify the maximum permissible variation of the first desired value 1a upward and downward. The difference in length between a and b yields the tolerance 1b. If the first feature size 1 on the mask then has a length b that deviates downward from the first desired value 1a, adaptation of the exposure dose, which means a higher exposure dose in this case, is used to effect exposure to a target dimension assigned to the first feature size 1 on the semiconductor wafer. This adaptation of the exposure dose results in the imaging of the first feature size 1 on the semiconductor wafer as if the desired value 1a were realized on the mask. However, the adaptation of the exposure dose has the effect that the second feature size 2 illustrated in FIG. 2 is also imaged in correspondingly lengthened fashion on the semiconductor wafer. If, on the mask, the first feature size 1 is realized with the length represented by the arrow b, then a length deviating upward from the second desired value 2a would correspond to the second feature size 2 on account of the adaptation of the exposure dose. This length is illustrated by the arrow b′ in the FIG. The same applies correspondingly to an upward deviation of the first feature size 1. The feature size deviating upward from the first desired value 1a is represented by the arrow a. Owing to the adaptation of the exposure dose, which means a lower exposure dose in this case, the second feature size 2 now acquires a lower value, represented by the arrow a′.

If the first desired value 1a of the first feature size 1 is realized on the mask, then no adaptations of the exposure dose are necessary and the second desired value 2a of the second feature size 2 is realized on the photomask. The desired values 1a, 2a are represented by the middle arrows in each case in FIG. 2.

For simplicity, the example shown assumes that the second feature size on the mask does not exhibit errors with regard to its length.

A calculation example will be used to explain the consequences result for the respective tolerances from what has been stated above. For the rectangular structure, on the mask, the first desired value for the first feature size, in this case the width of the rectangle, is predefined at 70 nm with a tolerance of ±10 nm. The desired value of 100 nm with a tolerance of ±12 nm is predefined for the second feature size, in this case, the length of the rectangle. If the first feature size attains a real value at the lower limit of the tolerance, i.e., real value=desired value−10 nm=60 nm, then the feature size is readjusted by +10 nm by adaptation of the exposure dose. Since the readjustment correspondingly affects the second feature size, this means that the second feature size acquires a value that deviates from the second desired value by +10 nm. An upper tolerance remainder of +2 nm remains, therefore, for the second feature size. A corresponding calculation holds true if the real value of the first feature size deviates by +10 nm from the desired value. A lower tolerance remainder of −2 nm then remains for the tolerance of the second feature size.

Given a tolerance of ±10 nm for the first feature size and a tolerance of ±12 nm specified for the second feature size, under the condition that the first feature size has the first desired value, a minimal residual tolerance for the second feature size of ±2 nm remains in a real case in which the first feature size on the photomask may vary within the predefined tolerance of ±10 nm.

The residual tolerance for the second feature size can be extended by correspondingly reducing the tolerance for the first feature size. A tolerance for the first feature size of ±6 nm and for the second feature size of ±6 nm would thus also be possible in this example. Alleviating the residual tolerance of the second feature size can be compensated for by intensifying the tolerance of the first feature size. Because the imaging process is set to the target dimension assigned to the most critical first feature size on the semiconductor wafer, deviations from desired dimensions on the semiconductor wafer result for the dimensions on the semiconductor wafer which are assigned to the further feature sizes on the mask, in accordance with adaptation of the exposure dose in the imaging device. The tolerances for the further feature sizes decrease on account of these deviations that are coupled to the discrepancy between the first feature size and the first desired value.

Additional further restrictions also result for the tolerances due to the fact that real mask fabrication processes have different systematic discrepancies between the feature sizes and desired values derived from the photomask design, for example. Structures having different structure sizes may turn out differently with regard to a discrepancy between the feature sizes and the desired value in a real photomask fabrication process, an effect which is dubbed linearity. Furthermore, identical structures may be formed differently in different surroundings, i.e., the proximity effect. When producing two-dimensional structures on the photomask, a further effect, referred to as line shortening, may occur and cause a systematic discrepancy between the feature size and the desired value.

For a stable photomask fabrication process, discrepancies between the feature sizes and the desired value which are caused by linearity, proximity, and line shortening behavior are stable and not subject to fluctuations.

Predefining very small permitted tolerances in production leads to a high reject rate in photomask fabrication, which affects the costs for a photomask, which are then fixed at a correspondingly high level.

### SUMMARY

A method for alleviating tolerances for feature sizes where maintaining photomask quality can extend limitations for feature sizes in the fabrication process for structures on photomasks to be imaged onto a semiconductor wafer, in order to avoid, in the case of a discrepancy between a first feature size to be provided on the photomask and a first desired value, restrictions of tolerances of further feature sizes to be provided on the photomask, said restrictions resulting from the discrepancy. The method includes a first predetermined desired value for the first feature size. The first desired value is assigned a first tolerance. The tolerance is understood to mean a range in which the feature size realized on the photomask is permitted to deviate from the desired value. The discrepancy between the first feature size and the first desired value is determined, for example, by a measurement. The discrepancy results as a difference between the feature size realized on the photomask and the desired value. According to the invention, the desired values to be assigned to the further feature sizes are calculated in a manner dependent on the discrepancy between the first feature size and the first desired value. The tolerances to be assigned to the calculated desired values are predefined. The tolerances on the photomask are predefined due to the calculation of the desired values, independently of the first tolerance and of the discrepancy between the first feature size and the first desired value.

The method according to the invention involves predefining a first desired value for a first feature size, for which an adaptation of imaging parameters, e.g., by adaptation of the exposure dose, of an imaging device is provided to achieve a target dimension to be assigned to the first feature size on the semiconductor wafer.

According to the invention, the desired values to be assigned to the further feature sizes on the photomask are calculated in a manner dependent on the discrepancy between the first feature size and the first desired value.

The desired values acquire a calculated value according to the invention which is provided to compensate for a deviation caused by adaptation of the imaging parameters from respective desired dimensions of the further feature sizes on the semiconductor wafer. As a result, the tolerances of the further feature sizes, which tolerances are to be assigned to the calculated desired values, can be freed of restrictions caused by the discrepancy between the first feature size and the first desired value and the resultant adaptation of the imaging parameters. The permitted tolerances of the feature sizes can again be provided independently of one another and of the deviation of the first feature size.

The feature sizes may, for example, be provided in an order of magnitude of the tolerance assigned to the respective imaged feature size on the semiconductor wafer.

The method according to the invention alleviates the tolerances of the further feature sizes in comparison with a conventional method, without improving the quality of the photomask. Calculating the further desired values in accordance with the invention takes account of the circumstance that discrepancies between the feature sizes and the desired value at the same location on the photomask typically have an identical effect on all the dimensions. This means that, for example, rectangular structures whose first feature size, i.e., width, is smaller than the first desired value are generally also made too small in other dimensions having the same tonal value, for example, the length. The tonal value is, in this case, understood to mean a light transmissivity of the structure, which may be transparent or opaque or semitransparent.

The method according to the invention can be employed, for example, for a specification of photomasks to alleviate the tolerances in the photomask fabrication process, thereby achieving a higher yield and thus a reduction of costs.

The first desired value is, for example, derived from a photomask design. In this case, the desired value on the photomask is provided such that a target dimension predefined on the wafer is achieved with the aid of the imaging device.

The first tolerance is provided to achieve a target dimension of the imaged first feature size on the semiconductor wafer by adaptation of parameters of the imaging device. Thus, if the first feature size lies within the first tolerance, then it is possible to achieve the target dimension on the wafer by adapting parameters of the imaging device.

Exposure parameters are provided as the adapted parameters. By adaptation of the exposure dose, a feature size that has turned out too large or too small on the photomask can again be imaged with the predefined target dimension on the semiconductor wafer.

Preferably, the desired values assigned in each case to the further feature sizes are calculated by the following computation specification: desired value=a structure dimension+/−the discrepancy between the first feature size and the first desired value.

According to the computation specification, the desired value results as the sum or difference formed from a structure dimension assigned to the respective feature size and the discrepancy between the first feature size and the first desired value. The following holds true for the first and the further feature sizes having the same tonal value: if the discrepancy between the first feature size and the first desired value is an upward deviation, i.e., if the first feature size is greater than the first desired value, then the plus sign is to be placed in the computation specification. If the discrepancy between the first feature size and the first desired value is a downward deviation, that is to say if the first feature size is less than the first desired value, then the minus sign is to be placed in the computation specification.

The computation specification holds true even if the first and the further features sizes have a different tonal value. If the first feature size is associated with a transparent structure and if the first feature size has an upward deviation from the desired value and if the further feature size is associated with an opaque structure, then the minus sign is to be placed in the computation specification. Depending on the combination of the tonal values and depending on whether the upward or downward deviation is present, either the minus sign or the plus sign is to be inserted in the computation specification.

The structure dimension assigned to the respective feature size is, for example, derived from the photomask design.

In an advantageous manner, the smallest feature size occurring on the photomask for the semiconductor process is chosen as the first feature size. The smallest feature size is generally also the most difficult to image dimensionally accurately. For this reason, it is advantageous to adapt the entire imaging process to the smallest feature size.

Preferably, the feature size occurring on the photomask which is functionally the most critical lithographically or electrically is chosen as the first feature size. The feature size with which a structure that is functionally significant electrically is fabricated in the semiconductor wafer is a critical feature size which should be imaged as dimensionally accurately as possible.

The tolerances are, for example, provided for the calculated desired values in an order of magnitude of the tolerance provided on the semiconductor wafer for the feature size that is respectively imaged onto the semiconductor wafer.

### BRIEF DESCRIPTION OF THE DRAWINGS

The invention is explained in more detail below with reference to the figures, in which:

FIG. 1 shows a detail from a photomask with a rectangular structure,

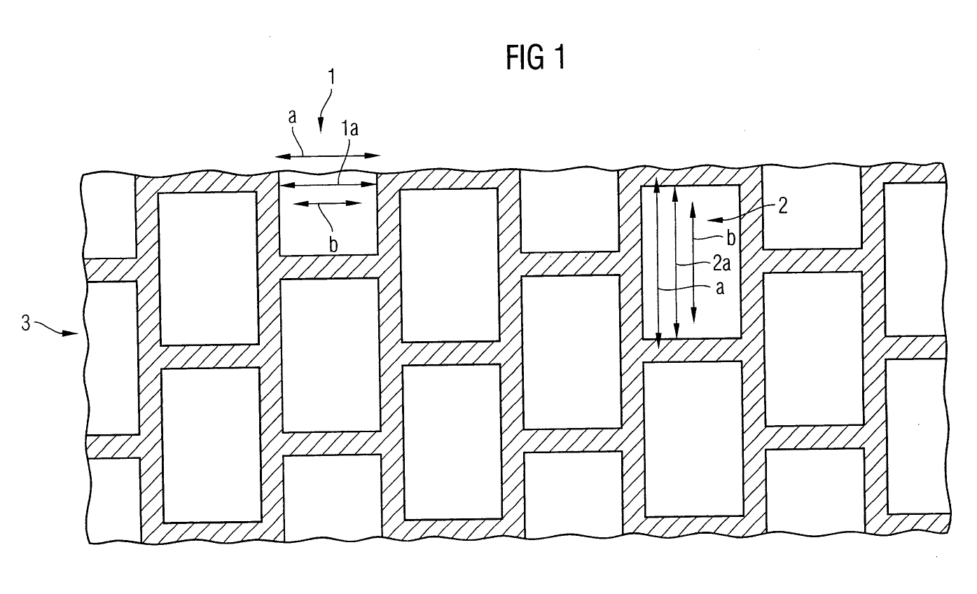

FIG. 2 shows a schematic illustration of two feature sizes,

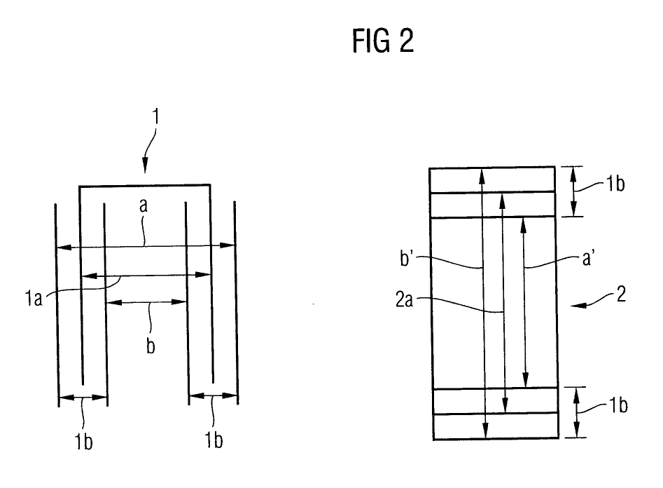

FIGS. 3A and 3B show a schematic illustration of tolerances that are predefined in accordance with the prior art, and

FIGS. 4A and 4B show a schematic illustration of tolerances that are predefined according to the invention.

### DETAILED DESCRIPTION

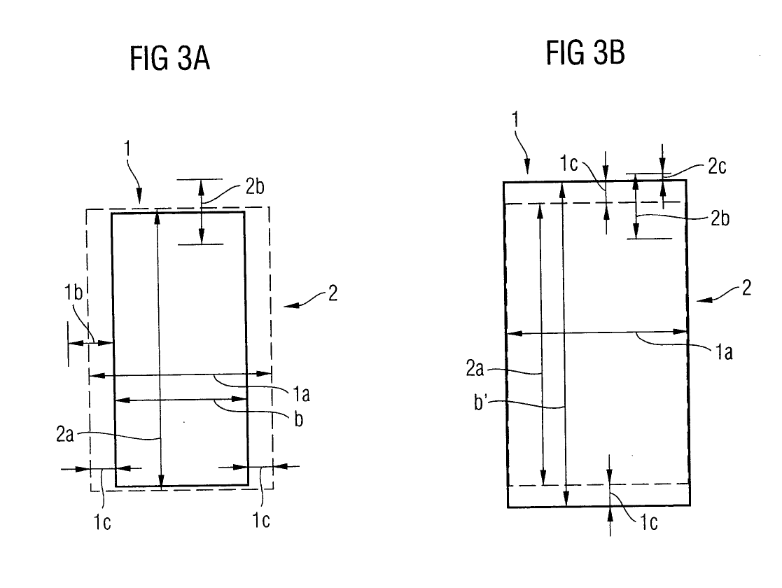

In accordance with FIGS. 3A and 3B, in a conventional method for specifying photomasks 3, desired values 1a, 2a derived from a photomask design, for example, are predefined for a first feature size 1 and further feature sizes 2. This exemplary embodiment is restricted to two feature sizes for simplicity. The first desired value 1a is allocated a first tolerance 1b. Tolerance is understood to mean the limiting range in which the real feature size is permitted to deviate from the desired value. The second desired value 2a is allocated a second tolerance 2b, under the condition that the first feature size 1 has the first desired value 1a. If this is not the case, rather the first feature size 1a has a discrepancy 1c, which lies at a lower tolerance limit, for example, then an adaptation of an exposure dose in an imaging device is carried out to achieve a target dimension assigned to the first feature size 1 on the semiconductor wafer. This means that adaptation of the exposure dose produces a situation as if the first feature size 1 had the first desired value 1a on the photomask. It is unfavorable that adaptation of the exposure dose concomitantly alters the imaging of the second feature size 2 onto the semiconductor wafer to the same extent. For the second feature size 2, adaptation of the exposure dose gives rise to a situation as if it were lengthened on the photomask 3 by the discrepancy 1c of the first feature size 1. The consequence is that what remains of the original tolerance 2b for the second feature size 2 is a residual tolerance 2c reduced by the discrepancy 1c.

FIG. 3A illustrates the first desired value 1a for the first feature size 1 and the second desired value 2a for the second feature size 2. The first desired value 1a is provided with the tolerance 1b depicted, and the second desired value 2a with the tolerance 2b depicted. As can be gathered from FIG. 3A, the real value of the first feature size 1 lies at the lower tolerance limit, represented by the arrow b. The feature sizes 1 and 2 specify the width and the length of a rectangle to be imaged onto the semiconductor wafer. The rectangle derived from a photomask design is represented by a dashed line in FIG. 3A and the rectangle formed in reality on the photomask is represented by a solid line.

FIG. 3B shows how the first feature size 1 and the second feature size 2 are altered if an adaptation of the exposure dose is carried out in a procedure directed at the target dimension of the first feature size 1 on the semiconductor wafer. For the first feature size 1, the situation as if it had attained the first desired value 1a is established on the photomask 3 after adaptation of the exposure dose. This is indicated in FIG. 3B by the long solid line lying on the dashed line, so that the dashed line under the solid line is no longer discernible. With regard to the second feature size 2, a deviation from the desired value 2a is present, as can be gathered from FIG. 3B. The arrow b′ indicates the second feature size 2 as would result after adaptation of the exposure dose on the semiconductor wafer. To a first approximation, for the structures on the exposed semiconductor wafer, a discrepancy between the second feature size 2 and the desired value 2a corresponds to the discrepancy 1c between the first feature size 1 and the first desired value 1a. As is illustrated in FIG. 3B, the result is then a minimal tolerance remainder 2c for the second feature size 2. A calculation example for the tolerance remainder 2c can be found in the introduction to the description.

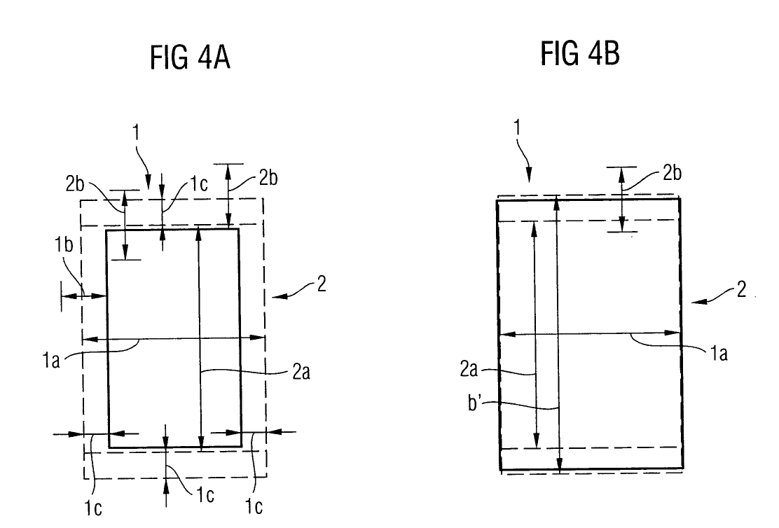

As is shown in FIG. 4, by the method according to the invention, the desired value 2a is calculated as a sum or difference between the structure dimension derived from the photomask design and the discrepancy 1c between the first feature size 1 and the first desired value 1a. The structure dimension corresponds to the conventional desired value 2a in accordance with FIG. 3. In this example, the desired value 2a according to the invention is shortened by the magnitude of the discrepancy 1c.

FIG. 4a differs from FIG. 3a by the shortened desired value 2a. This desired value 2a is represented by the arrow and by the dashed horizontal lines in the interior of the dashed rectangle. The shortened desired value 2a is provided with the tolerance 2b illustrated in FIG. 4a. Tolerance 2b corresponds to the tolerance with which the conventional desired value for the second feature size 2 can be provided, if the first desired value 1a for the first feature size 1 is realized on the photomask 3.

If the first desired value 1a is not realized on the photomask 3, after adaptation of the exposure dose in which the feature size 1 is exposed to the desired value 1a, the feature size 2 is also altered to a first approximation by the magnitude of the discrepancy 1c, so that the feature size 2 is again exposed to the structure dimension from the photomask design, if the real discrepancy of the second feature size 2 on the photomask 3 corresponds to the real discrepancy 1c of the first feature size 1. As a result, the full tolerance 2b is retained for the second feature size 2.

FIG. 4B illustrates, analogously to FIG. 3B, the situation that would result after adaptation of the exposure dose. The feature size 1 has attained the desired value 1a and the second feature size 2 has attained approximately the structure dimension derived from the photomask design. Thus, as indicated in FIG. 4B, the entire tolerance 2b remains for the second feature size 2.

The tolerances and desired values illustrated in FIGS. 4A and 4B will be illustrated once again below based on the example in the introduction to the description.

For the rectangular structure, on the photomask, the first desired value for the first feature size, in this case, the width of the rectangle, is predefined at 70 nm with a tolerance of ±10 nm. The structure dimension with 100 nm with a tolerance of ±12 nm is specified for the second feature size, in this case, the length of the rectangle. If the first feature size attains a real value at the lower limit of the tolerance, i.e., real value=desired value−10 nm=60 nm, then the feature size can be readjusted by +10 nm by adaptation of the exposure dose. The desired value for the second feature size then results as: desired value=structure dimension−discrepancy=100 nm−10 nm=90 nm. Since the readjustment correspondingly affects the second feature size, the second feature size acquires a value that deviates by +10 nm from the second desired value and thus again the value of the structure dimension of 100 nm if, as expected, the real value of the second feature size was likewise produced 10 nm too small. The permitted tolerance of ±12 nm is retained for the calculated desired value.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

List of Reference Symbols
1 first feature size
1a first desired value
1b first tolerance
1c discrepancy
2 further (second) feature size
2a desired value
2b tolerance
2c residual tolerance
3 photomask

1. A method for extending limitations for feature sizes (1, 2) in the fabrication process for structures on photomasks (3), to be imaged onto a semiconductor wafer, in order to reduce, in the case of a discrepancy (1c) between a first feature size (1) to be provided on the photomask (3) and a first desired value (1a), restrictions of tolerances (2b) of further feature sizes (2) to be provided on the photomask (3), the restrictions resulting from the discrepancy (1c), comprising:
predefining the first desired value (1a) of the first feature size (1);
predefining a first tolerance (1b) to be assigned to the first desired value (1a);
determining the discrepancy (1c) between the first feature size (1) and the first desired value (1a);
calculating desired values (2a) to be assigned to the further feature sizes (2) depending upon the discrepancy (1c) between the first feature size (1) and the first desired value (1a); and
predefining tolerances (2b) to be assigned to the calculated desired values (2a) by calculating the desired values (2a) independently of the first tolerance (1b) and of the discrepancy (1c) between the first feature size (1) and the first desired value (1a).

2. The method as claimed in claim 1, wherein the first desired value (1a) is derived from a photomask design.

3. The method as claimed in claim 1, wherein the first tolerance (1b) is provided to achieve a target dimension of the imaged first feature size (1) on the semiconductor wafer (3) by adaptation of parameters of an imaging device.

4. The method as claimed in claim 3, wherein exposure parameters are provided as the adapted parameters.

5. The method as claimed in claim 1, wherein calculating the desired values (2a) assigned to the further feature sizes (2) includes desired value (2a)=a structure dimension+/−the discrepancy (1c) between the first feature size (1) and the first desired value (1a).

6. The method as claimed in claim 5, wherein the structure dimension assigned to the respective feature size (2) is derived from a photomask design.

7. The method as claimed in claim 1, wherein the smallest feature size occurring on the photomask is the first feature size (1).

8. The method as claimed in claim 1, wherein the feature size occurring on the photomask, which is functionally the most critical lithographically or electrically, is the first feature size (1).

9. The method as claimed in claim 1, wherein the tolerances (2b) for the calculated desired values (2a) are provided in an order of magnitude of the tolerance assigned to the respectively imaged feature size (2) on the semiconductor wafer.
